(19) United States
(12) Patent Application Publication
(10) Pub. No.: US 2023/0140905 A1
(43) Pub. Date: May 11, 2023

(54) SYSTEMS AND METHODS FOR COMPLETION OPTIMIZATION FOR WATERFLOOD ASSETS

(71) Applicant: ConocoPhillips Company, Houston, TX (US)

(72) Inventors: Bo Hu, Houston, TX (US); Qing Chen, Houston, TX (US); Amir Nejad, Houston, TX (US); Xin Luo, Houston, TX (US); Christopher S. Olsen, Houston, TX (US); Robert C. Burton, Houston, TX (US); Liang Zhou, Houston, TX (US); Xin Jun Gou, Houston, TX (US); Liu Chao Zhang, Houston, TX (US); Junjing Zhang, Houston, TX (US); Iman Shahim, Houston, TX (US); Curt E. Schneider, Houston, TX (US); David D. Smith, Houston, TX (US); Andy Flowers, Houston, TX (US)

(21) Appl. No.: 17/982,799

(22) Filed: Nov. 8, 2022

Related U.S. Application Data
(60) Provisional application No. 63/276,928, filed on Nov. 8, 2021.

(51) Int. Cl. G06F 30/28; G06N 3/08

(52) U.S. Cl. CPC G06F 30/28; G06N 3/08

(57) ABSTRACT

Implementations described and claimed herein provide systems and methods for a framework to achieve completion optimization for waterflood field reservoirs. The proposed methodology leverages adequate data collection, preprocessing, subject matter expert knowledge-based feature engineering for geological, reservoir and completion inputs, and state-of-the-art machine-learning technologies, to indicate important production drivers, provide sensitivity analysis to quantify the impacts of the completion features, and ultimately achieve completion optimization. In this analytical framework, model-less feature ranking based on mutual information concept and model-dependent sensitivity analyses, in which a variety of machine-learning models are trained and validated, provides comprehensive multi-variant analyses that empower subject-matter experts to make a smarter decision in a timely manner.

### CROSS-REFERENCE TO RELATED APPLICATIONS

The present application claims priority to U.S. Provisional Patent Application 63/276,928 filed on Nov. 8, 2021, which is incorporated by reference in its entirety herein.

### FIELD

Aspects of the present disclosure relate generally to systems and methods for developing forecasts and models of oil wells and, more particularly, to predictive modeling to forecast oil and water production in complex waterflood operations utilizing deep learning with subject matter expert's domain knowledge.

### BACKGROUND

Production of hydrocarbons involves forming one or more wells in a subterranean formation to retrieve the hydrocarbons from beneath the surface. In some instances, multiple wells may be formed in what is known as a “field” to access one or more subsurface reservoirs. To improve the location of wells in the field, drilling of the wells, and transforming the drilled wells into producing wells (also referred to “completion”), predictive models may be built and used to forecast oil and water production from the wells. Previous solutions for completion optimization in waterflood fields mainly rely on traditional physics-based modeling tools with domain expert's interpretation, simple trending/statistical analyses, and trial-and-error learning. These methods can either suffer from certain biased assumptions used in physics-based models leading to less reliable results, or lack of analytical capability of unraveling complex interactions of reservoir and completion properties and quantifying the impacts of individual completion features on production to guide operation optimization.

Lacking accurate reservoir modeling and in-depth understanding of the interactions between reservoir and completion features makes it harder to model a typical water-flooded conventional reservoir. Current completion design workflows are often heavily reliant on traditional physics-based modeling with potentially unrealistic assumptions and engineer knowledge. Simple statistical analysis is similarly often inadequate to reveal high-dimension interactions of completion characteristics, making completion optimization extremely difficult.

It is with these observations in mind, among others, that various aspects of the present disclosure were conceived and developed.

### SUMMARY

Implementations described and claimed herein address the foregoing problems by providing systems and methods for generating an optimized completion model of a well field. In one implementation, raw field data from a plurality of wells of a well field may be combined with user-based data received from a user interface to generate an input dataset. Further, a plurality of completion forecast models may be trained based on the input dataset and utilizing a deep learning computing technique and an optimized production forecast model may be stored from the plurality of trained completion forecast models.

Other implementations are also described and recited herein. Further, while multiple implementations are disclosed, still other implementations of the presently disclosed technology will become apparent to those skilled in the art from the following detailed description, which shows and describes illustrative implementations of the presently disclosed technology. As will be realized, the presently disclosed technology is capable of modifications in various aspects, all without departing from the spirit and scope of the presently disclosed technology. Accordingly, the drawings and detailed description are to be regarded as illustrative in nature and not limiting.

### BRIEF DESCRIPTION OF THE DRAWINGS

FIG. 1 shows an example network environment that may implement various systems and methods discussed herein.

FIG. 2 is a block diagram illustrating example data flow for optimizing a well completion model utilizing deep thinking techniques.

FIG. 3 shows an example block diagram of a well completion optimization system for optimizing a well completion model.

FIG. 4 illustrates example operations for generating a optimizing a well completion model.

FIG. 5 shows an example computing system that may implement various systems and methods discussed herein.

### DETAILED DESCRIPTION

Aspects of the present disclosure involve systems and methods for well completion design optimization of waterflood assets utilizing machine learning and deep-thinking computational techniques combined with physics-based, subject matter expert knowledge. In one particular implementation, the systems and methods described herein may combine physics-based knowledge with machine learning techniques for oil-field production prediction to achieve an optimized well completion design. Completion and reservoir properties may be obtained from direct measurement and/or subject-matter expert's interpretations. Expert's domain knowledge can be embedded into data-driven workflows through appropriate data preparation and feature engineering. Completion features, combined with other reservoir properties and well interactions, may be used to build a variety of production prediction models with different modeling methodologies. Model-agnostic techniques may then be applied to interpret these data-driven models to indicate important production drivers, quantify the impacts of the completion features on production, and ultimately achieve completion optimization. Other advantages will be apparent from the present disclosure.

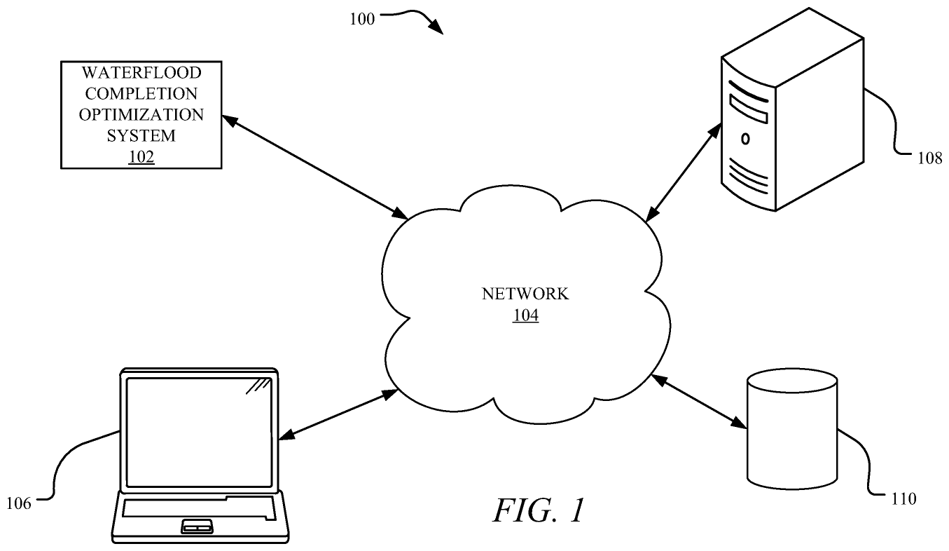

To begin a detailed discussion of an example asset development system 100, reference is made to FIG. 1. FIG. 1 illustrates an example network environment 100 for implementing the various systems and methods, as described herein. As depicted in FIG. 1, a network 104 is used by one or more computing or data storage devices for implementing the systems and methods for generating a well completion design optimization utilizing the waterflood completion optimization system 102. In one implementation, various components of the waterflood completion optimization system 102, one or more user devices 106, one or more databases 110, and/or other network components or computing devices described herein are communicatively connected to the network 104. Examples of the user devices 106 include a terminal, personal computer, a smart-phone, a tablet, a mobile computer, a workstation, and/or the like.

A server 108 may, in some instances, host the system. In one implementation, the server 108 also hosts a website or an application that users may visit to access the network environment 100, including the waterflood completion optimization system 102. The server 108 may be one single server, a plurality of servers with each such server being a physical server or a virtual machine, or a collection of both physical servers and virtual machines. In another implementation, a cloud hosts one or more components of the system. The waterflood completion optimization system 102, the user devices 106, the server 108, and other resources connected to the network 104 may access one or more additional servers for access to one or more websites, applications, web services interfaces, etc. that are used for reservoir modeling.

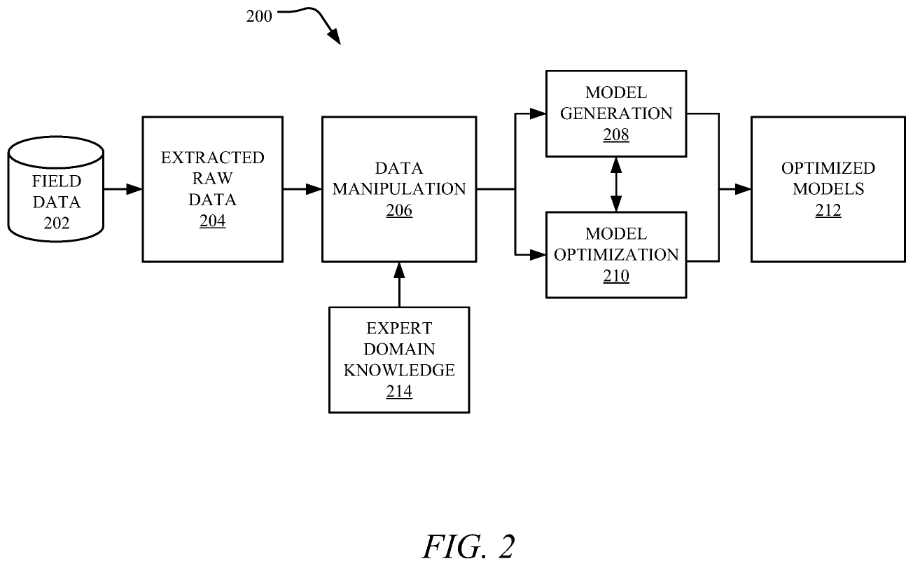

FIG. 2 is a block diagram illustrating an example data flow 200 for optimizing a well completion model utilizing deep thinking techniques. Through the data flow 200 of FIG. 2, an optimized waterflood well completion model may be generated incorporating field data with expert domain knowledge, resulting in more accurate completion models. In one particular implementation, the steps outlined in the data flow 200 of FIG. 2 may be executed by the waterflood completion optimization system 102 automatically or in response to inputs provided through a user interface to generate an optimized completion model. In other instances, however, any component of the network environment 100 may execute one or more applications as described in relation to the data flow 200 of FIG. 2.

The data flow 200 may include accessing a database 202 of field data and extracting raw data 204 as an input to a deep learning system. The extracted raw data 204 may include, among other types of data, completion parameters, daily production data, daily injection data, fault polygon shapefiles, geology data (such as geology maps), petrophysics data and/or maps, wellbore trajectory data, well event data, and the like. In general, the number and types of extracted data 204 may vary such that no particular type or size of field data 202 is required to generate the optimized well completion model. Rather, any datasets may be supplied as input to the waterflood completion optimization system 102, although additional data may result in a more detailed optimized well completion model provided by the waterflood completion optimization system.

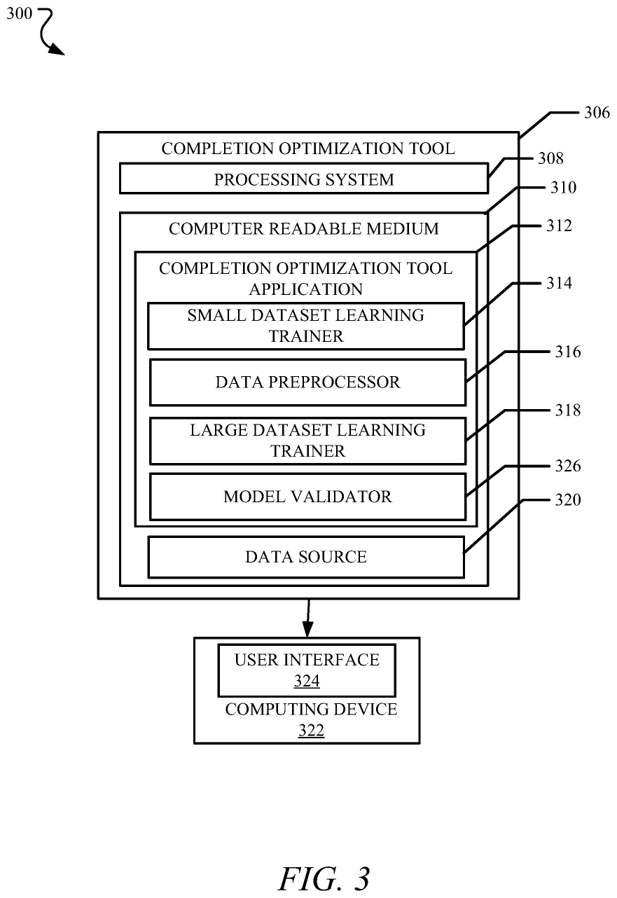

The extracted raw data 204 may be manipulated to generate a dataset for input into one or more production prediction models. In one example, the extracted raw data 204 may be combined with expert domain knowledge 214 to generate the input dataset. Expert domain knowledge 214 can be embedded into the extracted raw 204 through appropriate data preparation and feature engineering. For example, the expert domain knowledge 214 may be provided via a user interface, described in more detail below with reference to the block diagram 300 of FIG. 3. The provided data or knowledge 214 may be processed to be integrated with the extracted raw data 204. In this manner, the manipulated data 206 used as inputs to the various models may include completion and reservoir properties obtained from direct measurement (e.g., field data 202) and/or subject-matter expert's interpretations (e.g., expert domain knowledge 214).

The input dataset 206, including completion features combined with other reservoir properties and well interactions, may be used to build a variety of production prediction models 208 through different modeling methodologies. In some instances, the modeling methodologies may include deep thinking and/or machine learning techniques and may, in some implementations, be performed by one or more graphics processing units (GPUs). The multiple production prediction models 208 with enriched datasets may be built using different machine-learning algorithms, including but not limited to, tree-based modeling and deep neural network for different target variables, such as cumulative oil production, well flow efficiency, production decline rate and oil/liquid rates, etc. Such models can be properly trained using the GPU resources with built-in mathematical optimization and performance tracking mechanism. Interpretation of the generated models 208 may occur through model-agnostic techniques to extract or otherwise indicate important production drivers, quantify the impacts of the completion features on production, and ultimately achieve completion optimization 212. For example, the models may be validated with actual production data with satisfactory prediction accuracy and then interpreted by a set of model-agnostic techniques, such as individual conditional expectation (ICE), partial dependency plot (PDP), local surrogate (LIME) and SHapley additive explanations (SHAP). These model-agnostic methods not only help to interpret complex machine-learning models, but also provide sensitivity analysis on production drivers facilitating completion optimization.

Through the dataflow 200 of FIG. 2, an optimized well completion model 212 may be generated. By combining adequate physics understanding with innovative modeling techniques, the dataflow 200 may generate data-driven models to predict the production profiles of the wells with improved accuracy and computational efficiency than conventional reservoir simulators. Comprehensive completion analysis based on these modeling approaches is capable of explaining high-dimension interactions among reservoir and completion features so as to provide reliable recommendation for optimization.

FIG. 3 shows an example block diagram of a well completion optimization system 300 for generating optimized well completion models and/or predictions. In general, the system 300 may include a completion optimization tool 306. In one implementation, the completion optimization tool 306 may be a part of the dynamic waterflood completion optimization system 102 of FIG. 1. As shown in FIG. 3, the completion optimization tool 306 may be in communication with a computing device 322 providing a user interface 324. As explained in more detail below, the completion optimization tool 306 may be accessible to various users to generate an optimized well completion model based on field data 202 and expert domain knowledge 214.

In some instances, access to the completion optimization tool 306 may occur through the user interface 324 executed on the computing device 322. In one example, a user may provide one or more portions of the expert domain knowledge 214 via the user interface 324 executed by the computing device 322. In another example, a user may access the completion optimization tool 306 to generate a well completion model for a particular well and obtain well completion parameters that optimize the production of the modeled well.

As explained above, the completion optimization tool 306 may generate an optimized waterflood completion model 212 based on extracted raw data 204 from the field and expert domain knowledge 214. As such, the completion optimization tool 306 may include a completion optimization tool application 312 executed to perform one or more of the operations described herein. The completion optimization tool application 312 may be stored in a computer readable media 310 (e.g., memory) and executed on a processing system 308 of the completion optimization tool 306 or other type of computing system, such as that described below. For example, the completion optimization tool application 312 may include instructions that may be executed in an operating system environment, such as a Microsoft Windows™ operating system, a Linux operating system, or a UNIX operating system environment. The computer readable medium 310 includes volatile media, nonvolatile media, removable media, non-removable media, and/or another available medium. By way of example and not limitation, non-transitory computer readable medium 310 comprises computer storage media, such as non-transient storage memory, volatile media, nonvolatile media, removable media, and/or non-removable media implemented in a method or technology for storage of information, such as computer readable instructions, data structures, program modules, or other data.

The completion optimization tool application 312 may also utilize a data source 320 of the computer readable media 310 for storage of data and information associated with the completion optimization tool 306. For example, the completion optimization tool application 312 may store information associated with iterations of the generated completion models, extracted raw data 204 taken from a field data database 202, expert domain knowledge 214 provided via a user interface, model-agnostic optimization parameters, and the like. As described in more detail below, various generated models may be stored and used via the user interface 324 to simulate or otherwise determine field performance or conditions such that trained or optimized well completion models may be stored in the data source 320.

The completion optimization tool application 312 may include several components to perform one or more of the operations described herein. For example, the completion optimization tool application 312 may include a small dataset learning trainer 314 to provide statistical and unsupervised learning utilizing mutual information for relatively small datasets and interactive data analysis. For example, to analyze certain datasets, such as acid-job stimulation or well production for specific areas/platforms, of which the dataset size is too small to build reliable prediction models, descriptive analytics may be implemented by the small dataset learning trainer using scatter and box plots. In addition, embedding data functions may make the small dataset learning trainer 314 capable of providing feature ranking results for a subset of production data, in some instances dynamically selected by end users. The completion optimization tool application 312 may also include a data preprocessor 316 to execute data preprocess procedure. For example, the data preprocessor 316 may combine the extracted raw data 204 and the expert domain knowledge 214 such that the combined datasets may be applied as an input to one or more well completion models 208. In one instance, the data preprocessor 316 may convert one or more datasets into a standard protocol for input to the one or more completion models.

The completion optimization tool application 312 may also include a large dataset learning trainer 318 to generate and/or train one or more well completion models based on a combined input dataset 206 received from the data preprocessor 316. As explained above, the large dataset learning trainer 318 may include any machine learning or artificial intelligence techniques to generate a well completion model from the input dataset 206. In one particular implementation, the large dataset learning trainer 318 may employ a neural network to execute an artificial intelligence algorithm on the dataset 206 to generate one or more well completion models from the input dataset. As noted above, the large dataset learning trainer 318 may generate multiple production prediction models with enriched datasets built using different machine-learning algorithms including tree-based modeling and deep neural network for different target variables, such as cumulative oil production, well flow efficiency, production decline rate and oil/liquid rates, etc. Such models can be properly trained using GPU resources by the large dataset learning trainer 318 as described herein with built-in mathematical optimization and performance tracking.

A model validator 326 may also be included in the completion optimization tool application 312 to evaluate and verify the completion models generated by the application. In one example, this process may be iterative such that models may be generated, evaluated, refined or altered, and re-evaluated until an optimized model is determined. In some instances, this iterative process of model generation and optimization may be repeated thousands of times to enable well completion models with different hyper-parameters (aspects unique to the architecture of the model) to be trained and tested. During the training phase, custom loss functions may be used to coerce the model to make predictions within allowable ranges through greater penalty if a constraint is violated. In addition, the model validator 326 apply validation techniques to each generated model from the model generation system 208 to determine an accuracy of the model to the input datasets 206. Through a determined error obtained from the application of the various models to the model optimization 210, the completion optimization tool application 312 may determine how accurate or how closely the generated model or models correspond to the input dataset. The completion optimization tool application 312 may then alter the generated model based on the determined error to address and attempt to eliminate the error. This process of model generation and optimization may be repeated until the determined error of the model falls below a threshold value. In this manner, the model validator 326 may utilize techniques to generate or alter generated models that are trained, through the above-described iterative process, to provide an optimized well completion model.

It should be appreciated that the components described herein are provided only as examples, and that the application 312 may have different components, additional components, or fewer components than those described herein. For example, one or more components as described in FIG. 3 may be combined into a single component. As another example, certain components described herein may be encoded on, and executed on other computing systems. Further, more or fewer of the components discussed above with relation to the completion optimization tool 306 may be included with the tool, including additional components or modules included to perform the operations of the waterflood modeling system 102 discussed herein.

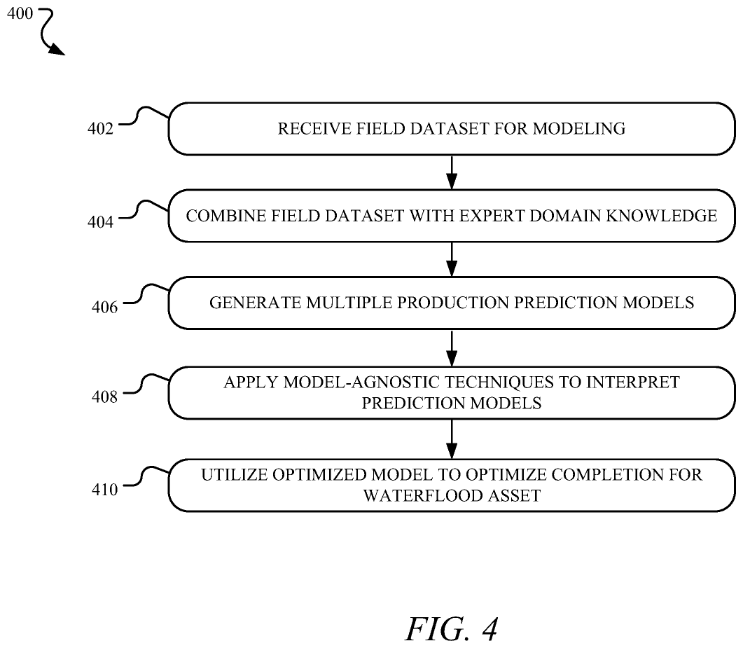

FIG. 4 illustrates example operations for generating a optimizing a well completion model. The operations may be performed by a computing device configured to execute any machine learning or artificial intelligent algorithm, including deep learning techniques. Such operations may be executed through control of one or more hardware components, one or more software programs, or a combination of both hardware and software components of the computing device. In one particular example, the operations of the illustrated method 400 may be performed by the completion optimization tool application 312 or other applications executed by a computing device.

Beginning in operation 402, the computing device may receive any field-related dataset 204 for inclusion in modeling an extraction field of wells. As explained above, such a dataset 204 may include field-specific data (such as geology data or maps of the field), general data (such as petrophysics data), and/or production data (such as completion parameters, daily production data, daily injection data, etc.). Such data may be obtained and stored in field database 202 illustrated in FIG. 2. In operation 404, one or more datasets of expert domain knowledge 214 may be combined with the field-related dataset 204 or otherwise included in an input dataset for one or more well completion models. In one instance, the expert domain knowledge 214 may be provided through a user interface in communication with the computing device.

In operation 406, the computing device of the completion optimization tool 306 may generate multiple production prediction models from the restructured dataset. The multiple models may be generated using different modeling methodologies based on varying production drivers for a well completion. For example, the multiple production prediction models may be built using different machine-learning algorithms, such as tree-based modeling and deep neural network for different target variables. In operation 408, model-agnostic techniques may be applied to the generated data-driven models to indicate important production drivers, quantify the impacts of the completion features on production, and the like. These agnostic methods not only help to interpret complex machine-learning models, but also provide sensitivity analysis on production drivers facilitating completion optimization.

In operation 410, the completion optimization tool 306 may utilize the optimized completion models generated above to provide one or more prediction outcomes for a well, including particular parameters of well production. Such model outputs may be used to generate new waterflood assets in a field. In one implementation, the optimized completion models may be accessed and utilized via a user interface to make a production prediction of an aspect of the waterflood asset field that accounts for data obtained from all or a portion of the wells of the field and/or expert domain knowledge.

The completion optimization framework disclosed herein is a fully data-driven workflow with a suite of machine-learning tools that individually serve for different scenarios and use cases. Descriptive, predictive & prescriptive analytics may be applied to unravel complex interactions among geological, reservoir and completion features through adequate data extraction, transformation, loading (ETL), model building and interpretation. The completion optimization tool is an innovative methodology/framework to achieve completion optimization for waterflood field reservoirs. Well completion is normally designed by exercising traditional physics-based modeling tools combined with domain expert's interpretation. The increasing complexity of the waterflood field brings growing challenges to traditional physics-based methods to represent reservoir characteristics. As a result, some design recommendations based on these methods have been less reliable and sub-optimal, leading to trial-and-error learning which can be time-consuming and cost-ineffective. The proposed methodology, leveraging adequate data collection, preprocessing, subject matter expert knowledge-based feature engineering for geological, reservoir and completion inputs, and state-of-the-art machine-learning technologies, is capable of indicating important production drivers, providing sensitivity analysis to quantify the impacts of the completion features and ultimately achieving completion optimization. In this analytical framework, model-less feature ranking based on mutual information concept and model-dependent sensitivity analyses, in which a variety of machine-learning models are trained and validated, provide comprehensive multi-variant analyses that empower subject-matter experts to make a smarter decision in a timely manner.

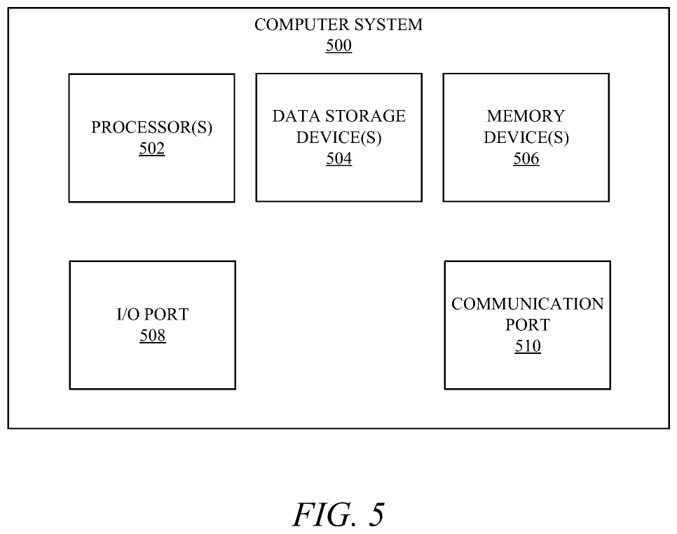

Discussing now FIG. 5, a detailed description of an example computing system 500 having one or more computing units that may implement various systems and methods discussed herein is provided. The computing system 500 may be applicable to the dynamic waterflood modeling system 102 of FIG. 1, the system 100, and other computing or network devices. It will be appreciated that specific implementations of these devices may be of differing possible specific computing architectures not all of which are specifically discussed herein but will be understood by those of ordinary skill in the art.

The computer system 500 may be a computing system is capable of executing a computer program product to execute a computer process. Data and program files may be input to the computer system 500, which reads the files and executes the programs therein. Some of the elements of the computer system 500 are shown in FIG. 5, including one or more hardware processors 502, one or more data storage devices 504, one or more memory devices 508, and/or one or more ports 508-510. Additionally, other elements that will be recognized by those skilled in the art may be included in the computing system 500 but are not explicitly depicted in FIG. 5 or discussed further herein. Various elements of the computer system 500 may communicate with one another by way of one or more communication buses, point-to-point communication paths, or other communication means not explicitly depicted in FIG. 5.

The processor 502 may include, for example, a central processing unit (CPU), a microprocessor, a microcontroller, a digital signal processor (DSP), and/or one or more internal levels of cache. There may be one or more processors 502, such that the processor 502 comprises a single central-processing unit, or a plurality of processing units capable of executing instructions and performing operations in parallel with each other, commonly referred to as a parallel processing environment.

The computer system 500 may be a conventional computer, a distributed computer, or any other type of computer, such as one or more external computers made available via a cloud computing architecture. The presently described technology is optionally implemented in software stored on the data stored device(s) 504, stored on the memory device(s) 506, and/or communicated via one or more of the ports 508-510, thereby transforming the computer system 500 in FIG. 5 to a special purpose machine for implementing the operations described herein. Examples of the computer system 500 include personal computers, terminals, workstations, mobile phones, tablets, laptops, personal computers, multimedia consoles, gaming consoles, set top boxes, and the like.

The one or more data storage devices 504 may include any non-volatile data storage device capable of storing data generated or employed within the computing system 500, such as computer executable instructions for performing a computer process, which may include instructions of both application programs and an operating system (OS) that manages the various components of the computing system 500. The data storage devices 504 may include, without limitation, magnetic disk drives, optical disk drives, solid state drives (SSDs), flash drives, and the like. The data storage devices 504 may include removable data storage media, non-removable data storage media, and/or external storage devices made available via a wired or wireless network architecture with such computer program products, including one or more database management products, web server products, application server products, and/or other additional software components. Examples of removable data storage media include Compact Disc Read-Only Memory (CD-ROM), Digital Versatile Disc Read-Only Memory (DVD-ROM), magneto-optical disks, flash drives, and the like. Examples of non-removable data storage media include internal magnetic hard disks, SSDs, and the like. The one or more memory devices 506 may include volatile memory (e.g., dynamic random access memory (DRAM), static random access memory (SRAM), etc.) and/or non-volatile memory (e.g., read-only memory (ROM), flash memory, etc.).

Computer program products containing mechanisms to effectuate the systems and methods in accordance with the presently described technology may reside in the data storage devices 504 and/or the memory devices 506, which may be referred to as machine-readable media. It will be appreciated that machine-readable media may include any tangible non-transitory medium that is capable of storing or encoding instructions to perform any one or more of the operations of the present disclosure for execution by a machine or that is capable of storing or encoding data structures and/or modules utilized by or associated with such instructions. Machine-readable media may include a single medium or multiple media (e.g., a centralized or distributed database, and/or associated caches and servers) that store the one or more executable instructions or data structures.

In some implementations, the computer system 500 includes one or more ports, such as an input/output (I/O) port 508 and a communication port 510, for communicating with other computing, network, or reservoir development devices. It will be appreciated that the ports 508-510 may be combined or separate and that more or fewer ports may be included in the computer system 500.

The I/O port 508 may be connected to an I/O device, or other device, by which information is input to or output from the computing system 500. Such I/O devices may include, without limitation, one or more input devices, output devices, and/or environment transducer devices.

In one implementation, the input devices convert a human-generated signal, such as, human voice, physical movement, physical touch or pressure, and/or the like, into electrical signals as input data into the computing system 500 via the I/O port 508. Similarly, the output devices may convert electrical signals received from computing system 500 via the I/O port 508 into signals that may be sensed as output by a human, such as sound, light, and/or touch. The input device may be an alphanumeric input device, including alphanumeric and other keys for communicating information and/or command selections to the processor 502 via the I/O port 508. The input device may be another type of user input device including, but not limited to: direction and selection control devices, such as a mouse, a trackball, cursor direction keys, a joystick, and/or a wheel; one or more sensors, such as a camera, a microphone, a positional sensor, an orientation sensor, a gravitational sensor, an inertial sensor, and/or an accelerometer; and/or a touch-sensitive display screen (“touchscreen”). The output devices may include, without limitation, a display, a touchscreen, a speaker, a tactile and/or haptic output device, and/or the like. In some implementations, the input device and the output device may be the same device, for example, in the case of a touchscreen.

The environment transducer devices convert one form of energy or signal into another for input into or output from the computing system 500 via the I/O port 508. For example, an electrical signal generated within the computing system 500 may be converted to another type of signal, and/or vice-versa. In one implementation, the environment transducer devices sense characteristics or aspects of an environment local to or remote from the computing device 500, such as, light, sound, temperature, pressure, magnetic field, electric field, chemical properties, physical movement, orientation, acceleration, gravity, and/or the like. Further, the environment transducer devices may generate signals to impose some effect on the environment either local to or remote from the example computing device 500, such as, physical movement of some object (e.g., a mechanical actuator), heating or cooling of a substance, adding a chemical substance, and/or the like.

In one implementation, a communication port 510 is connected to a network by way of which the computer system 500 may receive network data useful in executing the methods and systems set out herein as well as transmitting information and network configuration changes determined thereby. Stated differently, the communication port 510 connects the computer system 500 to one or more communication interface devices configured to transmit and/or receive information between the computing system 500 and other devices by way of one or more wired or wireless communication networks or connections. Examples of such networks or connections include, without limitation, Universal Serial Bus (USB), Ethernet, Wi-Fi, Bluetooth®, Near Field Communication (NFC), Long-Term Evolution (LTE), and so on. One or more such communication interface devices may be utilized via the communication port 510 to communicate one or more other machines, either directly over a point-to-point communication path, over a wide area network (WAN) (e.g., the Internet), over a local area network (LAN), over a cellular (e.g., third generation (3G) or fourth generation (4G) or fifth generation (5G) network), or over another communication means. Further, the communication port 510 may communicate with an antenna or other link for electromagnetic signal transmission and/or reception.

In an example implementation, waterflood model data, and software and other modules and services may be embodied by instructions stored on the data storage devices 504 and/or the memory devices 506 and executed by the processor 502. The computer system 500 may be integrated with or otherwise form part of the dynamic waterflood modeling system 102.

The system set forth in FIG. 5 is but one possible example of a computer system that may employ or be configured in accordance with aspects of the present disclosure. It will be appreciated that other non-transitory tangible computer-readable storage media storing computer-executable instructions for implementing the presently disclosed technology on a computing system may be utilized.

In the present disclosure, the methods disclosed may be implemented as sets of instructions or software readable by a device. Further, it is understood that the specific order or hierarchy of steps in the methods disclosed are instances of example approaches. Based upon design preferences, it is understood that the specific order or hierarchy of steps in the method can be rearranged while remaining within the disclosed subject matter. The accompanying method claims present elements of the various steps in a sample order, and are not necessarily meant to be limited to the specific order or hierarchy presented.

The described disclosure may be provided as a computer program product, or software, that may include a non-transitory machine-readable medium having stored thereon instructions, which may be used to program a computer system (or other electronic devices) to perform a process according to the present disclosure. A machine-readable medium includes any mechanism for storing information in a form (e.g., software, processing application) readable by a machine (e.g., a computer). The machine-readable medium may include, but is not limited to, magnetic storage medium, optical storage medium; magneto-optical storage medium, read only memory (ROM); random access memory (RAM); erasable programmable memory (e.g., EPROM and EEPROM); flash memory; or other types of medium suitable for storing electronic instructions.

While the present disclosure has been described with reference to various implementations, it will be understood that these implementations are illustrative and that the scope of the present disclosure is not limited to them. Many variations, modifications, additions, and improvements are possible. More generally, embodiments in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A method for generating a forecast model of a well field, the method comprising:
combining raw field data from a plurality of wells of the well field with user-based data received from a user interface to generate an input dataset;
training, based on the input dataset and utilizing a deep learning computing technique, a plurality of completion forecast models; and
generating an optimized production forecast model from the plurality of trained completion forecast models.

2. The method of claim 1, further comprising:
interpreting the plurality of completion forecast models based on one or more model-agnostic evaluation techniques.

3. The method of claim 1, wherein training of the plurality of completion forecast models comprises executing a plurality of different modeling techniques with the input dataset.

4. The method of claim 3, wherein the plurality of different modeling techniques is at least one of a tree-based modeling technique or a deep neural network technique.

5. The method of claim 1, further comprising:
expanding the raw field data through one of a scatter plot of the raw field data or a box plot of the raw field data.

6. The method of claim 1, further comprising:
displaying, on the user interface, a generated result of the optimized production forecast model based on a well completion dataset

7. The method of claim 1, further comprising:
recursively executing the optimized production forecast model to generate a completion
prediction of a well of the well field, the optimized production forecast model receiving measured production data from the field data.

8. One or more tangible non-transitory computer-readable storage media storing computer-executable instructions for performing a computer process on a computing system, the computer process comprising:
combining raw field data from a plurality of wells of a well field with user-based data received from a user interface to generate an input dataset;
training, based on the input dataset and utilizing a deep learning computing technique, a plurality of completion forecast models; and
generating an optimized production forecast model from the plurality of trained completion forecast models.

9. The one or more tangible non-transitory computer-readable storage media of claim 8, the computer process further comprising:
interpreting the plurality of completion forecast models based on one or more model-agnostic evaluation techniques.

10. The one or more tangible non-transitory computer-readable storage media of claim 8, wherein training of the plurality of completion forecast models comprises executing a plurality of different modeling techniques with the input dataset.

11. The one or more tangible non-transitory computer-readable storage media of claim 10, wherein the plurality of different modeling techniques is at least one of a tree-based modeling technique or a deep neural network technique.

12. The one or more tangible non-transitory computer-readable storage media of claim 8, the computer process further comprising:
expanding the raw field data through one of a scatter plot of the raw field data or a box plot of the raw field data.

13. The one or more tangible non-transitory computer-readable storage media of claim 8, the computer process further comprising:
displaying, on the user interface, a generated result of the optimized production forecast model based on a well completion dataset

14. The one or more tangible non-transitory computer-readable storage media of claim 8, the computer process further comprising:
recursively executing the optimized production forecast model to generate a completion prediction of a well of the well field, the optimized production forecast model receiving measured production data from the field data.

15. A system for generating a forecast model of a well field, the system comprising:
a waterflood completion optimization system having at least one processor configured to train a plurality of completion forecast models using a deep learning computing technique and based on an input dataset, the input dataset generated by combining raw field data from a plurality of wells of the well field with user-based data, the waterflood completion optimization system generating an optimized production forecast model from the plurality of trained completion forecast models.

16. The system of claim 15, wherein the user-based data is received from a user interface presented by a user device.

17. The system of claim 16, wherein the user interface is configured to present a generated result of the optimized production forecast model based on a well completion dataset.

18. The system of claim 15, wherein training of the plurality of completion forecast models comprises executing a plurality of different modeling techniques with the input dataset.

19. The system of claim 15, wherein waterflood completion optimization system expands the raw field data through one of a scatter plot of the raw field data or a box plot of the raw field data.

20. The system of claim 15, wherein waterflood completion optimization system recursively executes the optimized production forecast model to generate a completion prediction of a well of the well field, the optimized production forecast model receiving measured production data from the field data.
